(19) United States
(12) Patent Application Publication
(10) Pub. No.: US 2024/0347351 A1
(43) Pub. Date: Oct. 17, 2024

(54) SUBSTRATE-PROCESSING METHOD AND SUBSTRATE-PROCESSING APPARATUS

(71) Applicant: Tokyo Electron Limited, Tokyo (JP)

(72) Inventors: Hitoshi KATO, Iwate (JP); Hiroyuki KIKUCHI, Iwate (JP); Hidenobu SATO, Iwate (JP); Masato YONEZAWA, Iwate (JP)

(21) Appl. No.: 18/626,693

(22) Filed: Apr. 4, 2024

(30) Foreign Application Priority Data
Apr. 14, 2023 (JP) 2023-066223

(51) Int. Cl. H01L 21/67; H01J 37/32; H01L 21/687

(52) U.S. Cl. CPC H01L 21/67069; H01J 37/32449; H01L 21/67098; H01L 21/68764; H01J 2237/334

(57) ABSTRACT

A substrate-processing method includes a) providing a substrate in which a recess is formed, where the substrate has a surface where a silicon oxide film is exposed, and b) generating a plasma using a gas mixture to etch the silicon oxide film with the plasma, where the gas mixture includes a trifluoromethane gas, an oxygen-containing gas, and a hydrogen-containing gas.

### CROSS-REFERENCE TO RELATED APPLICATIONS

This application is based upon and claims priority to Japanese Patent Application No. 2023-066223, filed on Apr. 14, 2023, the entire contents of which are incorporated herein by reference.

### BACKGROUND

### 1. Field of the Invention

The present disclosure relates to substrate-processing methods and substrate-processing apparatuses.

### 2. Description of the Related Art

In, for example, Japanese Laid-Open Patent Publication No. 2016-162930, a technology of supplying fluorine radicals to a silicon oxide film formed on a substrate to etch the silicon oxide film is known.

### SUMMARY

According to one aspect of the present disclosure, a substrate-processing method includes a) providing a substrate in which a recess is formed, the substrate having a surface where a silicon oxide film is exposed, and b) generating a plasma using a gas mixture to etch the silicon oxide film with the plasma, the gas mixture including a trifluoromethane gas, an oxygen-containing gas, and a hydrogen-containing gas.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a schematic cross-sectional view illustrating a substrate-processing apparatus according to the present disclosure;

FIG. 2 is a schematic perspective view illustrating a structure inside a vacuum chamber of the substrate-processing apparatus of FIG. 1;

FIG. 3 is a schematic plan view illustrating the structure inside the vacuum chamber of the substrate-processing apparatus of FIG. 1;

FIG. 4 is a schematic cross-sectional view concentrically taken along a rotary table disposed in the vacuum chamber of the substrate-processing apparatus of FIG. 1;

FIG. 5 is another schematic cross-sectional view of the substrate-processing apparatus of FIG. 1;

FIG. 6 is a schematic cross-sectional view illustrating a plasma generator;

FIG. 7 is another schematic cross-sectional view illustrating the plasma generator;

FIG. 8 is a schematic top view illustrating the plasma generator;

FIG. 9 is a flowchart depicting the substrate-processing method according to the present disclosure;

FIGS. 10A to 10C are schematic cross-sectional views illustrating the substrate-processing method according to the present disclosure;

FIGS. 11A to 11C are diagrams for depicting etching reactions of a CHF₃ gas; and

FIG. 12 is a graph describing a relationship between a position relative to a depth direction of a recess and an etching amount.

### DETAILED DESCRIPTION

The present disclosure provides a technique of controlling an etching shape when a film formed in a recess is etched.

Hereinafter, non-limiting embodiments of the present disclosure will be described with reference to the attached drawings. Throughout the attached drawings, the same or corresponding members or parts are designated by the same or corresponding reference symbols, and duplicate description thereof will be omitted.

### [Substrate-Processing Apparatus]

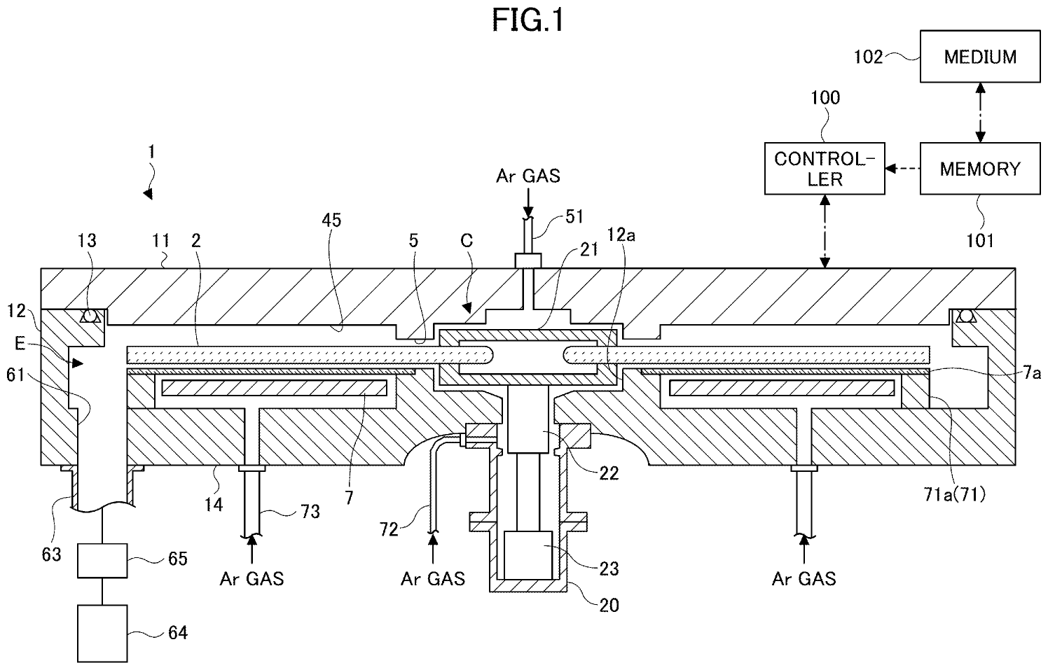

An embodiment of a substrate-processing apparatus suitable for performing the substrate-processing method according to the present disclosure will be described. With reference to FIGS. 1 to 3, the substrate-processing apparatus includes a flat vacuum chamber 1 having a substantially circular planar shape, and a rotary table 2 disposed in the vacuum chamber 1. The rotary table 2 has a center of rotation aligned with the center of the vacuum chamber 1. The vacuum chamber 1 includes a container body 12 and a top plate 11. The container body 12 has a cylindrical shape having a closed bottom. The top plate 11 is detachably and airtightly disposed on a top face of the container body 12 via a sealing member 13, such as an O-ring and the like.

The rotary table 2 is fixed to a cylindrical core 21 at a central portion of the vacuum chamber. The core 21 is fixed on a top end of a rotary shaft 22 that extends vertically. The rotary shaft 22 passes through a bottom portion 14 of the vacuum chamber 1, and a bottom end of the rotary shaft 22 is attached to a driver 23 that rotates the rotary shaft 22 around a vertical axis. The rotary shaft 22 and the driver 23 are contained in a case 20 that has a shape of a tube where a top face of the tube is open. A flange portion provided at the top face of the case 20 is airtightly attached to a bottom face of the bottom portion 14 of the vacuum chamber 1 so that the airtightness of an interior of the case 20 is maintained against the exterior of the case 20.

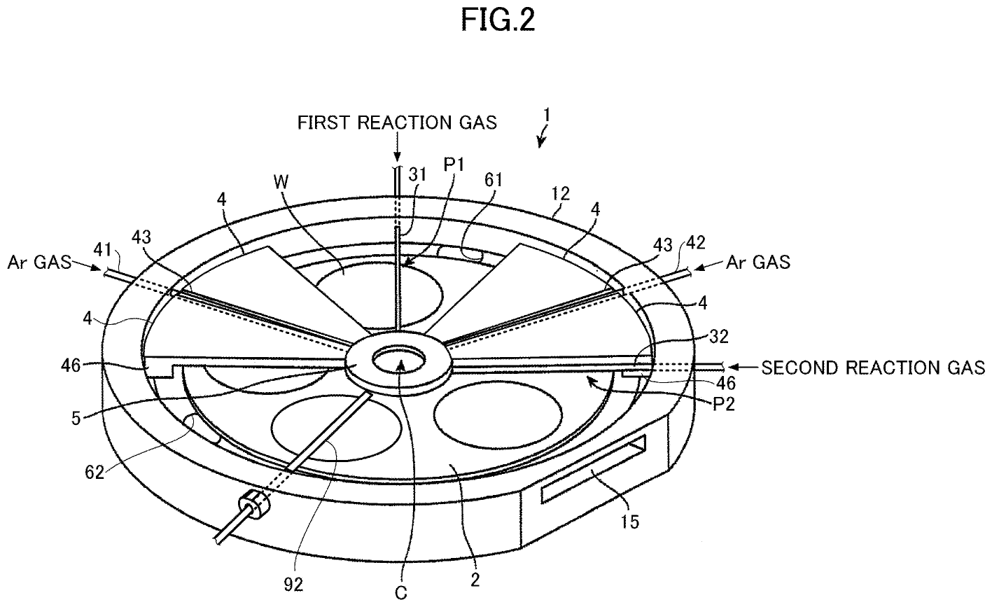

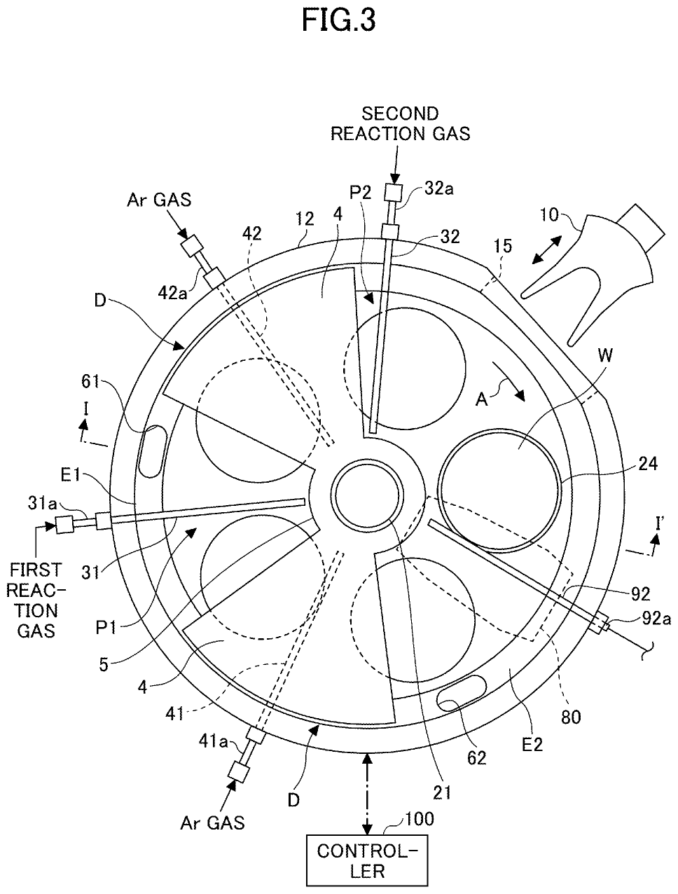

A plurality of circular mounting portions 24 (5 portions in the illustrated example) for mounting a substrate W thereon are formed in a surface portion of the rotary table 2 as illustrated in FIGS. 2 and 3. For example, the substrate W may be a semiconductor wafer, such as a silicon wafer and the like. For convenience, a substrate W is depicted in only one mounting portion 24. The mounting portion 24 has an inner diameter slightly larger than a diameter of the substrate W, for example, by 4 mm, and a depth substantially equal to a thickness of the substrate W. As the substrate W is set in the mounting portion 24, the surface of the substrate W is therefore approximately at the same height as the surface of the rotary table 2 (a region where the substrate W is not mounted). For example, through-holes (not illustrated) where three lifting pins are passed through, respectively, are formed in the bottom face of the mounting portion 24. The three lifting pins support the back face of the substrate W to lift and lower the substrate W.

FIGS. 2 and 3 are views for describing the structure inside the vacuum chamber 1, and the illustration of the top plate 11 is omitted for the convenience of the description. As illustrated in FIGS. 2 and 3, reaction gas nozzles 31 and 32, separation gas nozzles 41 and 42, and a processing gas nozzle 92 are disposed above the rotary table 2. The reaction gas nozzles 31 and 32, separation gas nozzles 41 and 42, and processing gas nozzle 92 are spaced apart from one another relative to a circumferential direction of the vacuum chamber 1. In the illustrated example, the processing gas nozzle 92, the separation gas nozzle 41, the reaction gas nozzle 31, the separation gas nozzle 42, and the reaction gas nozzle 32 are arranged in the clockwise direction (the rotational direction of the rotary table 2) in this order from the below-described loading port 15. The reaction gas nozzles 31 and 32, the separation gas nozzles 41 and 42, and the processing gas nozzle 92 are formed of, for example, quartz. Gas inlet ports 31a, 32a, 41a, 42a, and 92a (FIG. 3) of the reaction gas nozzles 31, 32, the separation gas nozzles 41 and 42, and the processing gas nozzle 92 are fixed on a peripheral wall of the container body 12. The gas inlet ports 31a, 32a, 41a, 42a, and 92a (FIG. 3) are proximal ends of the reaction gas nozzles 31, 32, the separation gas nozzles 41 and 42, and the processing gas nozzle 92, respectively. In the manner as described, the reaction gas nozzles 31 and 32, the separation gas nozzles 41 and 42, and the processing gas nozzle 92 are each inserted from the peripheral wall of the vacuum chamber 1 into the vacuum chamber 1 to extend along a radius direction of the container body 12 to be parallel to the rotary table 2.

As simplified and illustrated with a dashed line in FIG. 3, a plasma generator 80 is disposed above the processing gas nozzle 92. The plasma generator 80 will be described below.

The reaction gas nozzle 31 is connected to a first reaction gas source (not illustrated) via a pipe, a flow rate controller, and the like, which are not illustrated. The first reaction gas is a silicon-containing gas. For example, the silicon-containing gas is an aminosilane-based gas. For example, the aminosilane-based gas is a diisopropylaminosilane (DIPAS) gas or a tris(dimethylamino) silane (3DMAS) gas.

The reaction gas nozzle 32 is connected to a second reaction gas source (not illustrated) via a pipe, a flow rate controller, and the like, which are not illustrated. For example, the second reaction gas is an oxidizing gas. For example, the oxidizing gas is an ozone (O₃) gas, an oxygen (O₂) gas, water (H₂O), a hydrogen peroxide (H₂O₂) gas, or a gas mixture including two or more of the foregoing.

The separation gas nozzles 41 and 42 are each connected to a separation gas source (not illustrated) via a pipe, a flow rate controlling valve, and the like, which are not illustrated. For example, the separation gas is an argon (Ar) gas. The separation gas may be a nitrogen (N₂) gas.

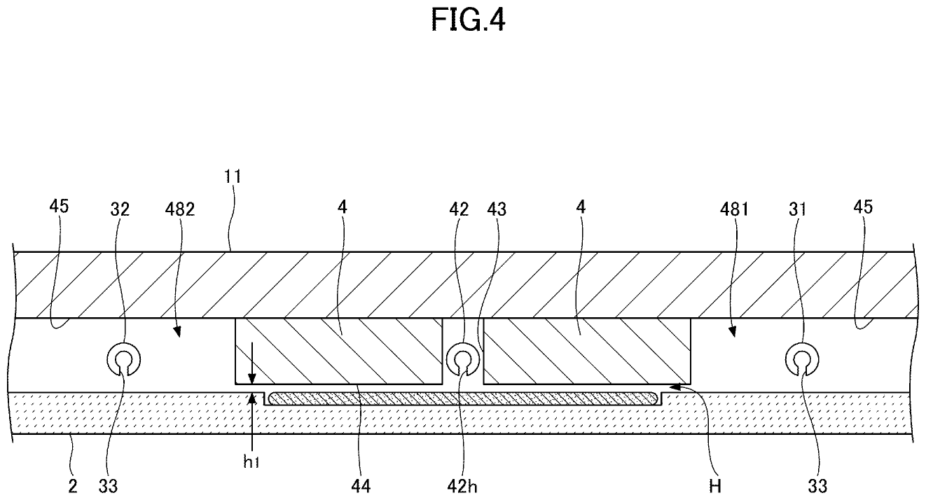

In each of the reaction gas nozzles 31 and 32, a plurality of gas discharge holes 33 (FIG. 4) opening towards the rotary table 2 are aligned along a length direction of each of the reaction gas nozzles 31 and 32, for example, at an interval of 10 mm. The region below the reaction gas nozzle 31 is a first processing region P1 for allowing a substrate W to adsorb a silicon-containing gas. The region below the reaction gas nozzle 32 is a second processing region P2 for oxidizing the silicon-containing gas, which has been adsorbed on the substrate W in the first processing region P1.

With reference to FIGS. 2 and 3, two projections 4 are disposed inside the vacuum chamber 1. The projections 4 each constitute a separation region D together with the separation gas nozzle 41 or 42. To this end, as described below, the projections are disposed on the back face of the top plate 11 to project towards the rotary table 2. Each projection 4 has a fan-like planar shape in which a tip of the fan is cut out into an arc shape. Each projection 4 is arranged, for example, in a manner such that an inner arc of the projection 4 is linked to a protrusion 5 (described below) and an outer arc of the projection 4 is aligned with an inner circumference face of the container body 12 of the vacuum chamber 1.

FIG. 4 illustrates a cross-section of the vacuum chamber 1 concentrically taken along the rotary table 2 from the reaction gas nozzle 31 to the reaction gas nozzle 32. As illustrated, the projections 4 are arranged on the back face of the top plate 11, thus the interior of the vacuum chamber 1 has a flat and low ceiling 44 (first ceiling) that is a bottom face of the projection 4, and a ceiling 45 (second ceiling) that is positioned on both sides of the ceiling 44 in the circumferential direction and is higher than the ceiling 44. The ceiling 44 is a fan-like planar shape where a tip of the fan is cut out into an arc shape. As illustrated, a groove 43 extending along the radius direction is formed at a center of the projection 4 relative to the circumferential direction, and the separation gas nozzle 42 is held in the groove 43. A groove 43 is similarly formed in the other projection 4, and the separation gas nozzle 41 is held in the groove 43. The reaction gas nozzles 31 and 32 are disposed in the space 481 and 482 below the high ceiling 45, respectively. The reaction gas nozzles 31 and 32 are both disposed near the substrate W, spaced apart from the ceiling 45.

In the separation gas nozzle 42, a plurality of gas discharge holes 42h (see FIG. 4) opening towards the rotary table 2 are aligned along a length direction of the separation gas nozzle 42, for example, at the interval of 10 mm. Also in the separation gas nozzle 41, similar to the separation gas nozzle 42, a plurality of gas discharge holes (not illustrated) opening towards the rotary table 2 are aligned along a length direction of the separation gas nozzle 41, for example, at the interval of 10 mm.

The ceiling 44 forms a separation space H, which is a narrow space, with the rotary table 2. As a separation gas is supplied from the gas discharge holes 42h of the separation gas nozzle 42, the separation gas passes through the separation space H, followed by flowing into the space 481 and the space 482. Since the volume of the separation space H is smaller than the volume of the spaces 481 and 482, the above-described flow of the separation gas can cause the pressure of the separation space H to become higher than the pressure of the spaces 481 and 482. Specifically, the separation space H having high pressure is formed between the space 481 and the space 482. Moreover, the separation gas flowing from the separation space H into the spaces 481 and 482 acts as a counter flow against the first reaction gas from the first processing region P1 and the second reaction gas from the second processing region P2. Because of the counter flow of the separation gas, the first reaction gas from the first processing region P1 and the second reaction gas from the second processing region P2 are separated from each other by the separation space H. Therefore, mixing of the first reaction gas and the second reaction gas inside the vacuum chamber 1 is minimized to inhibit a reaction between the first reaction gas and the second reaction gas.

A height h1 of the ceiling 44 relative to the top face of the rotary table 2 is set to be a suitable height for increasing pressure of the separation space H compared to the pressure of the space 481 and 482, considering the pressure inside the vacuum chamber 1, the revolution speed of the rotary table 2, a feeding rate of the separation gas, and the like during processing of the substrate.

A protrusion 5 (FIGS. 2 and 3) is disposed on the bottom face of the top plate 11 to surround the periphery of the core 21 that fixes the rotary table 2. For example, the protrusion 5 is continuous with a portion of the projection 4 at the side where the center of the rotation is present, and the bottom face of the projection 4 is formed to have the same height as the ceiling 44.

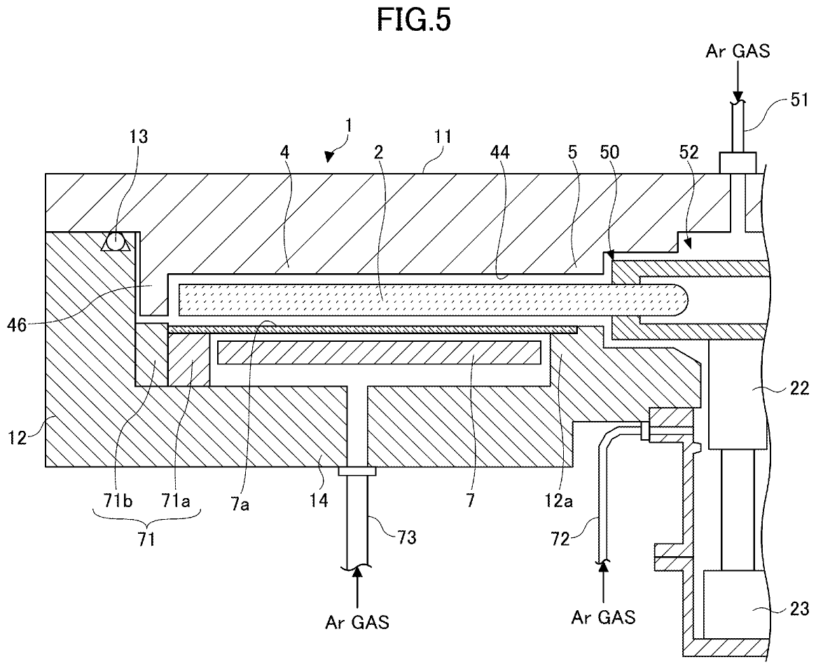

Previously referred FIG. 1 is a cross-sectional view taken along the line I-I′ of FIG. 3, and illustrates a region where the ceiling 45 is disposed. FIG. 5 is a cross-sectional view illustrating a region where the ceiling 44 is disposed. As illustrated in FIG. 5, a bending portion 46 is formed on the fringe (the portion near the outer circumference of the vacuum chamber 1) of the projection 4 having the fan-like shape. The bending portion 46 bends into an L-shape facing the outer edge face of the rotary table 2. Similar to the projection 4, the bending portion 46 inhibits entry of the reaction gases from the both sides of the separation region D to inhibit the two reaction gases from mixing together. The projection 4 having the fan-like shape is disposed on the top plate 11, and the top plate 11 is detachably mounted on the container body 12. Therefore, there is a small gap between the outer circumferential face of the bending portion 46 and the container body 12. The gap between the inner circumferential face of the bending portion 46 and the outer edge face of the rotary table 2, and the gap between the outer circumferential face of the bending portion 46 and the container body 12 are each set, for example, in the similar manner as the height of the ceiling 44 with respect to the top face of the rotary table 2.

In the separation region D, the inner circumferential wall of the container body 12 is formed as a vertical face that is arranged to be close to the outer circumferential face of the bending portion 46, as illustrated in FIG. 5. In the regions other than the separation region D, the inner circumferential wall of the container body 12 is recessed outwards, for example, from a portion facing the outer edge face of the rotary table 2 to the bottom portion 14, as illustrated in FIG. 1. For the convenience of the description, the recessed portion having a substantially rectangular cross-sectional shape is described as an exhaust region E hereinafter. Specifically, the exhaust region connected to the first processing region P1 is described as a first exhaust region E1, and the exhaust region connected to the second processing region P2 is described as a second exhaust region E2. As illustrated in FIGS. 1 and 3, a first exhaust port 61 and a second exhaust port 62 are formed at the bottom of the first exhaust region E1 and the bottom of the second exhaust region E2, respectively. As illustrated in FIG. 1, the first exhaust port 61 and the second exhaust port 62 are each connected to a vacuum pump 64 via an exhaust pipe 63. The exhaust pipe 63 is equipped with a pressure controller 65.

As illustrated in FIGS. 1 and 5, a heater unit 7 is disposed in the space between the rotary table 2 and the bottom portion 14 of the vacuum chamber 1. The heater unit 7 heats a substrate W mounted on the rotary table 2 through the rotary table 2 at a temperature determined by a process recipe. An annular cover member 71 is disposed below the region near the outer edge of the rotary table 2 (FIG. 5). The cover member 71 partitions the interior of the vacuum chamber 1 into the atmosphere from the upper space of the rotary table 2 to the exhaust regions E1 and E2 and the atmosphere in which the heater unit 7 is disposed, thereby inhibiting entry of gases into the region below the rotary table 2. The cover member 71 includes an inner member 71a and an outer member 71b. The inner member 71a is disposed in a manner such that the inner member 71a faces the outer edge of the rotary table 2 and a region slightly outward of the outer edge from the bottom side of the rotary table 2. The outer member 71b is disposed between the inner member 71a and the inner wall of the vacuum chamber 1. The outer member 71b is disposed in a manner such that the outer member 71b comes close to the bending portion 46 at the bottom of the bending portion 46 formed on the fringe of the projection 4 in the separation region D. The inner member 71a surrounds the entire periphery of the heater unit 7 below the outer edge of the rotary table 2 (and below the region slightly outward of the outer edge).

The section of the bottom portion 14 that is nearer to the rotation center than the space in which the heater unit 7 is disposed is projected upwards to be close to the core 21 near the center of the bottom face of the rotary table 2, thereby forming a protrusion 12a. A small space is formed between the protrusion 12a and the core 21. Moreover, the inner circumferential face of the through hole of the bottom portion 14 through which the rotary shaft 22 passes and the rotary shaft 22 form a small gap. The above-mentioned small spaces are connected to the case 20. A purge gas supply pipe 72 is disposed at the case 20. The purge gas supply pipe 72 supplies a purge gas into the small space to purge. For example, the purge gas is an Ar gas. The purge gas may be a nitrogen gas. A plurality of purge gas supply pipes 73 for purging the space in which the heater unit 7 is disposed are disposed in the bottom portion 14 of the vacuum chamber 1 below the heater unit 7 at the predetermined angular interval in the circumferential direction. One purge gas supply pipe 73 is illustrated in FIG. 5. A lid member 7a is disposed between the heater unit 7 and the rotary table 2. The lid member 7a covers the area from the inner circumferential wall of the outer member 71b (the top face of the inner member 71a) to the top end of the protrusion 12a in the circumferential direction to inhibit entry of gases into the region where the heater unit 7 is disposed. The lid member 7a is formed of, for example, quartz.

A separation gas supply pipe 51 is connected to the center of the top plate 11 of the vacuum chamber 1. The separation gas supply pipe 51 supplies a separation gas to a space 52 between the top plate 11 and the core 21. The separation gas supplied to the space 52 passes through the small space 50 between the protrusion 5 and the rotary table 2 to be discharged towards the periphery along the surface of the rotary table 2 where the substrate is mounted. The separation gas contributes to retain the pressure of the space 50 higher than the pressure of the space 481 and the pressure of the space 482. Therefore, the space 50 inhibits the first reaction gas supplied to the first processing region P1 and the second reaction gas supplied to the second processing region P2 from passing through the central region C to be mixed together. Specifically, the space 50 (or the central region C) functions similarly to the separation space H (or the separation region D).

As illustrated in FIGS. 2 and 3, a loading port 15 is formed in the side wall of the vacuum chamber 1. The loading port 15 is used for transporting the substrate W between an external transfer arm 10 and the rotary table 2. The loading port 15 is open and closed by a gate valve that is not illustrated. The substrate W is passed to or from the transfer arm 10 at the position facing the loading port 15. A lifting pin for loading and a lifting mechanism for the lifting pin (both not illustrated) are disposed at the position that is below the rotary table 2 and corresponds to the loading position. The lifting pin for loading passes through the mounting portion 24 to lift the substrate W from the back face of the substrate W.

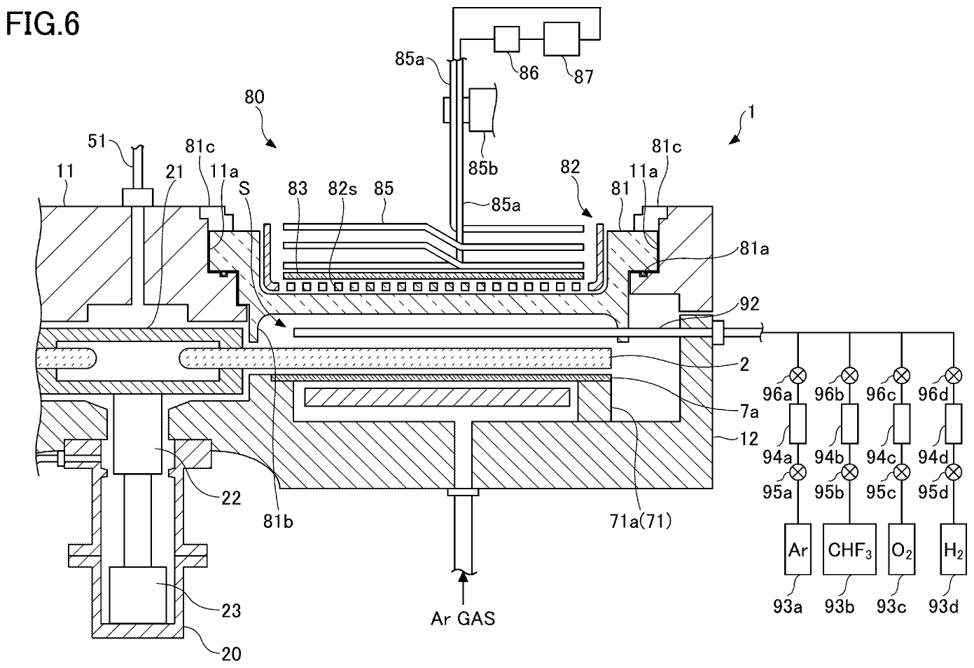

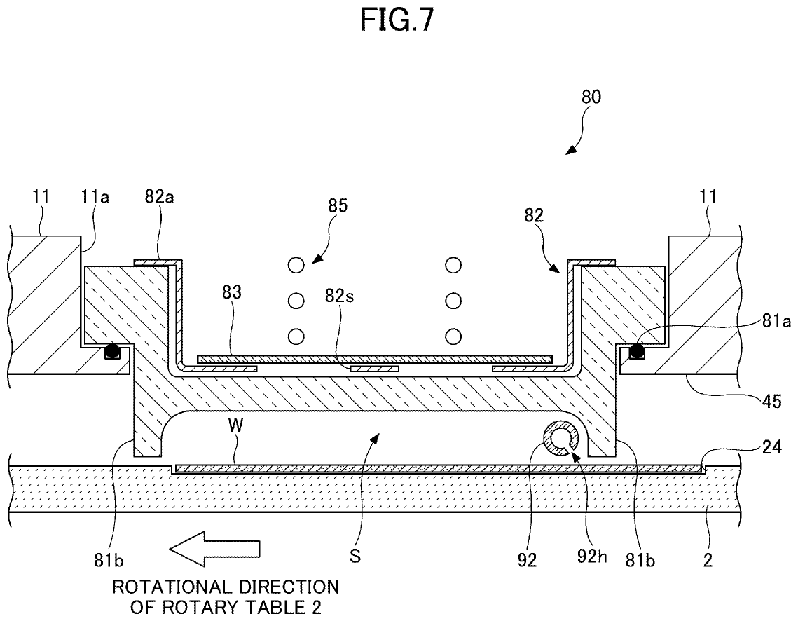

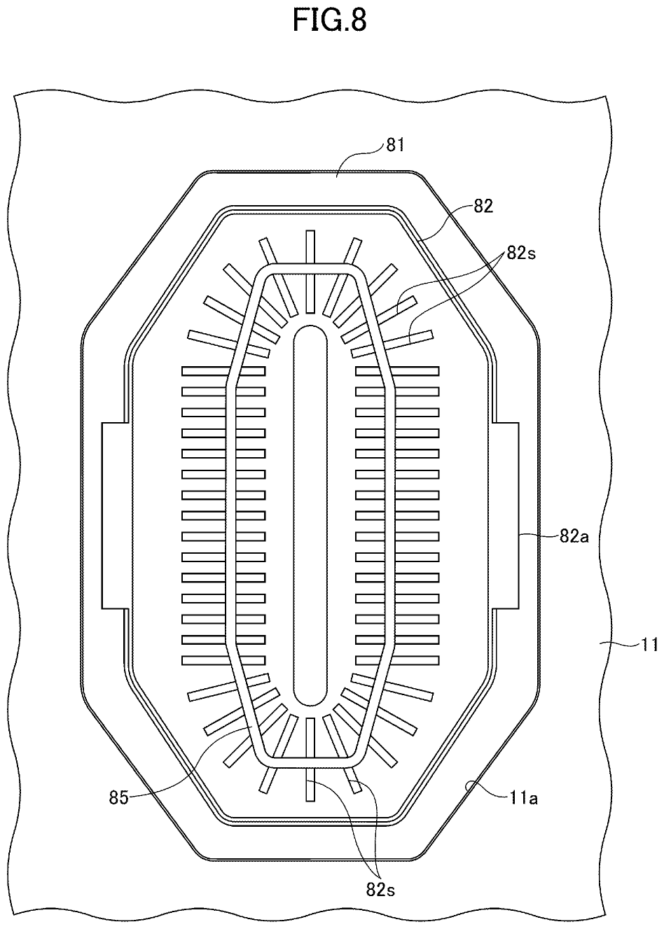

A plasma generator 80 will be described with reference to FIGS. 6 to 8. FIG. 6 is a schematic cross-sectional view of the plasma generator 80 taken along the radius direction of the rotary table 2. FIG. 7 is a schematic cross-sectional view of the plasma generator 80 taken along the direction orthogonal to the radius direction of the rotary table 2. FIG. 8 is a top view schematically illustrating the plasma generator 80. For the convenience of illustration, some of the members are omitted or simplified in FIGS. 6 to 8.

With reference to FIG. 6, the plasma generator 80 includes a frame member 81, a Faraday shield 82, an insulation plate 83, and an antenna 85. The frame member 81 is formed of a high-frequency-wave permeable material. The frame member 81 has a recess that dips from a top face of the frame member 81. The frame member 81 is fitted in an opening 11a formed in the top plate 11. The Faraday shield 82 is held in the recess of the frame member 81, and has a substantially box shape where a top of the box is open. The insulation plate 83 is disposed on the bottom face of the Faraday shield 82. The antenna 85 is supported above the insulation plate 83. The antenna 85 is in a shape of a coil where a top planar shape of the coil is substantially an octagon.

The opening 11a of the top plate 11 has steps. A groove is formed in one of the steps, where the groove is formed along the entire periphery of the step. A sealing member 81a, such as an O-ring and the like, is fitted in the groove. The frame member 81 has steps corresponding to the steps of the opening 11a. Once the frame member 81 is fitted into the opening 11a, a back face of one of the steps is brought into contact with the sealing member 81a fitted into the opening 11a. As a result, airtightness between the top plate 11 and the frame member 81 is maintained. As illustrated in FIG. 6, a press member 81c is disposed along the periphery of the frame member 81 fitted into the opening 11a of the top plate 11. The frame member 81 is pressed downwards against the top plate 11 by the press member 81c. Therefore, airtightness between the top plate 11 and the frame member 81 can be assuredly maintained.

The bottom face of the frame member 81 faces the rotary table 2 inside the vacuum chamber 1. A protrusion 81b projecting downwards (towards the rotary table 2) is disposed over the entire periphery of the bottom face of the frame member 81. The bottom face of the protrusion 81b comes close to the surface of the rotary table 2. The space above the rotary table 2 (referred to as interior space S, hereinafter) is partitioned off by the protrusion 81b, the surface of the rotary table 2, and the bottom face of the frame member 81. The gap between the bottom face of the protrusion 81b and the surface of the rotary table 2 may be substantially the same as the height h1 of the top plate 11 relative to the top face of the rotary table 2 in the separation space H (FIG. 4).

The processing gas nozzle 92 passes through the protrusion 81b to extend to the interior space S. The processing gas nozzle 92 is connected to a source 93a charged with an Ar gas, a source 93b charged with a trifluoromethane (CHF₃) gas, a source 93c charged with an oxygen (O₂) gas, and a source 93d charged with a hydrogen (H₂) gas. The processing gas nozzle 92 supplies a gas mixture, in which the Ar gas from the source 93a, the CHF₃ gas from the source 93b, the O₂ gas from the source 93c, and the H₂ gas from the source 93d are mixed, to the interior space S. The gas mixture in which the Ar gas, the CHF₃ gas, the O₂ gas, and the H₂ gas are mixed may be also referred to as an Ar/CHF₃/O₂/H₂ gas, hereinafter. The flow rates of the Ar gas, CHF₃ gas, O₂ gas, and H₂ gas from the sources 93a, 93b, 93c, and 93d are controlled by corresponding flow rate controllers 94a, 94b, 94c, and 94d, respectively. The supply and termination of the supply of the Ar gas, CHF₃ gas, O₂ gas, and H₂ gas from the sources 93a, 93b, 93c, and 93d to the interior space S are controlled by corresponding first valves 95a, 95b, 95c, and 95d and corresponding second valves 96a, 96b, 96c, and 96d, respectively. A source of a modifying gas such as an ammonia (NH₃) gas and the like may be connected to the processing gas nozzle 92.

In the processing gas nozzle 92, a plurality of discharge holes 92h are formed along a length direction of the processing gas nozzle 92 at the predetermined interval (e.g., 10 mm). The processing gas nozzle 92 discharges an Ar/CHF₃/O₂/H₂ gas from the discharge holes 92h. As illustrated in FIG. 7, the directions of the discharge holes 92h are shifted from the vertical direction relative to the rotary table 2 to the upstream direction relative to the rotational direction of the rotary table 2. Therefore, the gas mixture supplied from the processing gas nozzle 92 is discharged in the reverse direction to the rotational direction of the rotary table 2, specifically, the direction towards the gap between the bottom face of the protrusion 81b and the surface of the rotary table 2. Because of the above-described flow of the gas mixture, entry of the reaction gas or separation gas from the space below the ceiling 45, which is upstream of the plasma generator 80 in the rotational direction of the rotary table 2, into the interior space S can be suppressed. As described above, the protrusion 81b formed along the periphery of the bottom face of the frame member 81 is disposed near the surface of the rotary table 2. Therefore, the gas mixture discharged from the processing gas nozzle 92 can readily maintain the pressure of the interior space S high. The high pressure of the interior space S also contributes to inhibit entry of the reaction gas or the separation gas into the interior space S.

The Faraday shield 82 is formed of an electroconductive material, such as a metal, and is grounded (not illustrated). As illustrated in FIG. 8, a plurality of slits 82s are formed at the bottom of the Faraday shield 82. Each slit 82s extends substantially orthogonal to sides corresponding to the sides of the substantially octagonal planar shape of the antenna 85.

As illustrated in FIGS. 7 and 8, the Faraday shield 82 includes two supports 82a that bend outwards at the two positions on the upper edge of the Faraday shield 82. As the supports 82a are supported by the top face of the frame member 81, the Faraday shield 82 is supported at the predetermined position within the frame member 81.

The insulation plate 83 is formed of, for example, quartz. The insulation plate 83 is slightly smaller than the bottom face of the Faraday shield 82, and is mounted on the bottom face of the Faraday shield 82. The insulation plate 83 insulates the Faraday shield 82 from the antenna 85. High frequencies emitted from the antenna 85 are transmitted downwards through the insulation plate 83.

The antenna 85 is formed, for example, by coiling a copper hollow tube (pipe) into triple loops having a substantially octagonal planar shape. A coolant may be circulated through the pipe. The circulation of the coolant can inhibit elevation of the temperature of the antenna 85 to a high temperature due to high frequency waves supplied to the antenna 85. A stand 85a is disposed to the antenna 85, and the support 85b is attached to the stand 85a. The support 85b holds the antenna 85 in the predetermined position within the Faraday shield 82. A high frequency power source 87 is connected to the support 85b via a matching box 86. The high frequency power source 87 generates high frequency waves having a frequency of, for example, 13.56 MHZ.

In the plasma generator 80 having the above-described structure, a high frequency power is supplied from the high frequency power source 87 to the antenna 85 via the matching box 86, thereby causing the antenna 85 to generate an electromagnetic field. The electric-field component within the generated electromagnetic field is shielded by the Faraday shield 82 so that the electric-field component cannot be transmitted downwards through the Faraday shield 82. Conversely, the magnetic-field component is transmitted to the interior space S through the slits 82s of the Faraday shield 82. The magnetic-field component generates a plasma in an Ar/CHF₃/O₂/H₂ gas supplied from the processing gas nozzle 92.

As illustrated in FIG. 1, the substrate-processing apparatus includes a controller 100 composed of a computer configured to control movements of the entire apparatus. Programs for causing the substrate-processing apparatus to execute the below-described substrate-processing method under the control of the controller 100 are stored in a memory of the controller 100. The programs include a group of steps constructed so as to perform the below-described substrate-processing method. The programs are stored in a medium 102, such as a hard disk, a compact disk, a magneto-optical disk, a memory card, a flexible disk, and the like, and the stored programs are loaded onto a memory 101 by a predetermined reader to install the programs in the controller 100.

### [Substrate-Processing Method]

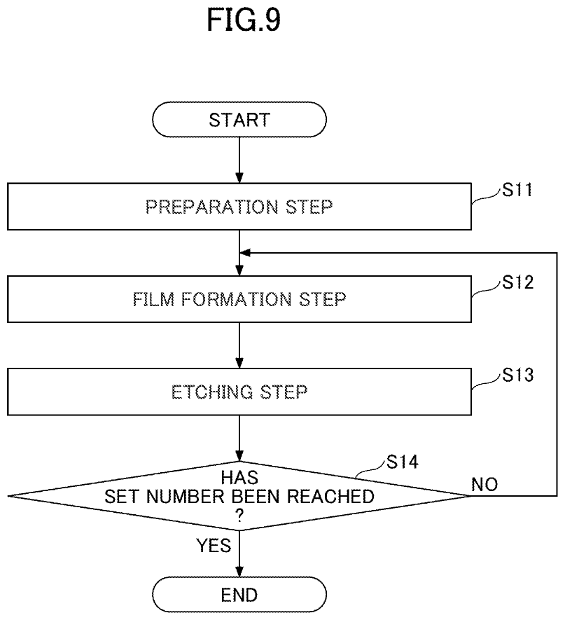

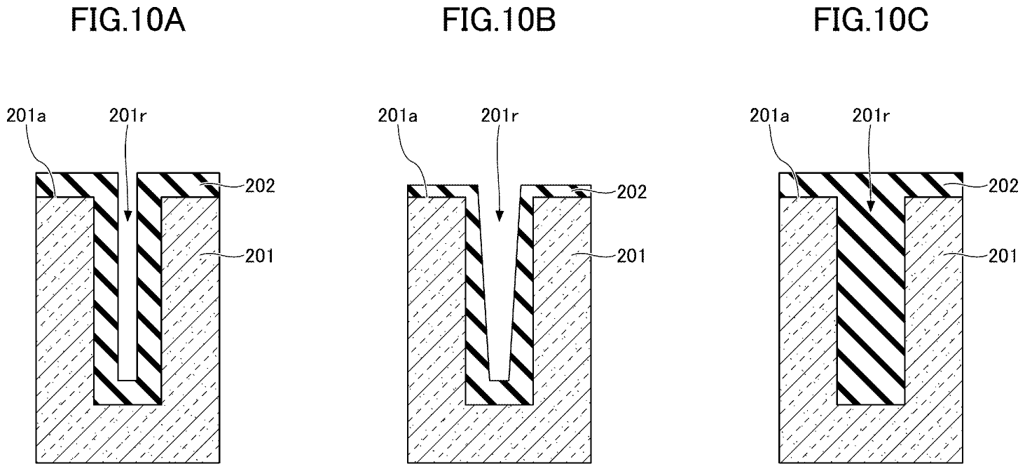

With reference to FIGS. 9 and 10, the substrate-processing method according to the present disclosure will be described through an example where the substrate-processing method is performed by the above-described substrate-processing apparatus. As illustrated in FIG. 9, the substrate-processing method includes a preparation step S11, a film formation step S12, an etching step S13, and a determining step S14.

The preparation step S11 includes providing of a substrate 201 having a recess 201r formed in a surface of the substrate 201. The substrate 201 is, for example, a silicon wafer. The recess 201r is, for example, a trench. The recess 201r may be a hole.

The film formation step S12 is performed after the preparation step S11. The film formation step S12 includes formation of a film, which is a reaction product between a silicon-containing gas and an oxidizing gas, on the recess 201r.

First, a gate valve, which is not illustrated, is open to load a substrate 201 into the mounting portion 24 of the rotary table 2 through the loading port 15 using the transfer arm 10. The loading of the substrate 201 is performed by rising a lifting pin, which is not illustrated, from the bottom of the vacuum chamber 1 through a through-hole formed at the bottom of each mounting portion 24 when the rotary table 2 is stopped at a position where the mounting portion 24 faces the loading port 15. While intermittently rotating the rotary table 2, the substrates 201 are delivered to load the substrates 201 into the five mounting portions 24 of the rotary table 2, respectively.

Subsequently, the gate valve is closed. After creating a vacuumed state within the vacuum chamber 1 by a vacuum pump 64, an Ar gas serving as a separation gas is discharged from the separation gas nozzles 41 and 42 at the predetermined flow rate, and an Ar gas is discharged from the separation gas supply pipe 51 and the purge gas supply pipes 72 and 73 at the predetermined flow rate. In this process, the interior of the vacuum chamber 1 is adjusted at the predetermined processing pressure by a pressure controller 65. Subsequently, the substrates 201 are heated by the heater unit 7 while rotating the rotary table 2 in the clockwise direction.

Next, a silicon-containing gas is supplied from the reaction gas nozzle 31 and an oxidizing gas is supplied from the reaction gas nozzle 32, without supplying an Ar/CHF₃/O₂/H₂ gas from the processing gas nozzle 92.

When the substrate 201 passes through the first processing region P1, the silicon-containing gas supplied from the reaction gas nozzle 31 is adsorbed on the top face 201a of the substrate 201 and the inner face of the recess 201r. By the rotation of the rotary table 2, the substrate 201 to which the silicon-containing gas is adsorbed is passed through the separation region D including the separation gas nozzle 42 to purge, followed by entering the second processing region P2. In the second processing region P2, a Si component included in the silicon-containing gas is oxidized by the oxidizing gas supplied from the reaction gas nozzle 32 to deposit silicon oxide (SiO₂), which is a reaction product, on the top face 201a of the substrate 201 and the inner face of the recess 201r.

The substrate 201 that has passed through the second processing region P2 passes through the separation region D including the separation gas nozzle 41 to purge, followed by re-entering the first processing region P1. Then, the silicon-containing gas supplied from the reaction gas nozzle 31 is adsorbed on the top face 201a of the substrate 201 and the inner face of the recess 201r.

As described above, the rotary table 2 is continuously rotated, while supplying the silicon-containing gas from the reaction gas nozzle 31 and the oxidizing gas from the reaction gas nozzle 32, without supplying an Ar/CHF₃/O₂/H₂ gas from the processing gas nozzle 92. As a result, as illustrated in FIG. 10A, a silicon oxide film 202 having a cross-sectional shape that follows the top face 201a of the substrate 201 and the inner face of the recess 201r is formed.

After the predetermined time lapse, supply of the silicon-containing gas from the reaction gas nozzle 31 is terminated, and supply of the oxidizing gas from the reaction gas nozzle 32 is terminated, thereby finishing the film formation step S12. The predetermined time lapse may be determined, for example, according to a targeted thickness of the silicon oxide film 202.

In the film formation step S12, a modifying gas may be supplied from the processing gas nozzle 92. In this case, the silicon oxide is modified every time the substrate 201 passes through the interior space S, thereby improving the quality of the silicon oxide film 202. In the film formation step S12, moreover, an Ar gas may be supplied from the processing gas nozzle 92.

The etching step S13 is performed after the film formation step S12. The etching step S13 includes generating a plasma using an Ar/CHF₃/O₂/H₂ gas to etch a silicon oxide film 202 with the generated plasma. The plasma generated using the Ar/CHF₃/O₂/H₂ gas may be also referred to as an Ar/CHF₃/O₂/H₂ plasma hereinafter.

In the etching step S13, the substrate 201 is heated by the heater unit 7, while rotating the rotary table 2 in the clockwise direction. Next, the Ar/CHF₃/O₂/H₂ gas is supplied from the processing gas nozzle 92, and a high frequency power having a frequency of 13.56 MHz is applied to the antenna 85 of the plasma generator 80, without supplying the silicon-containing gas and the oxidizing gas from the reaction gas nozzles 31 and 32, respectively. As a result, an Ar/CHF₃/O₂/H₂ plasma is generated in the interior space S. Every time the substrate 201 passes through the interior space S, the substrate 201 is exposed to the Ar/CHF₃/O₂/H₂ plasma so that the silicon oxide film 202 is etched.

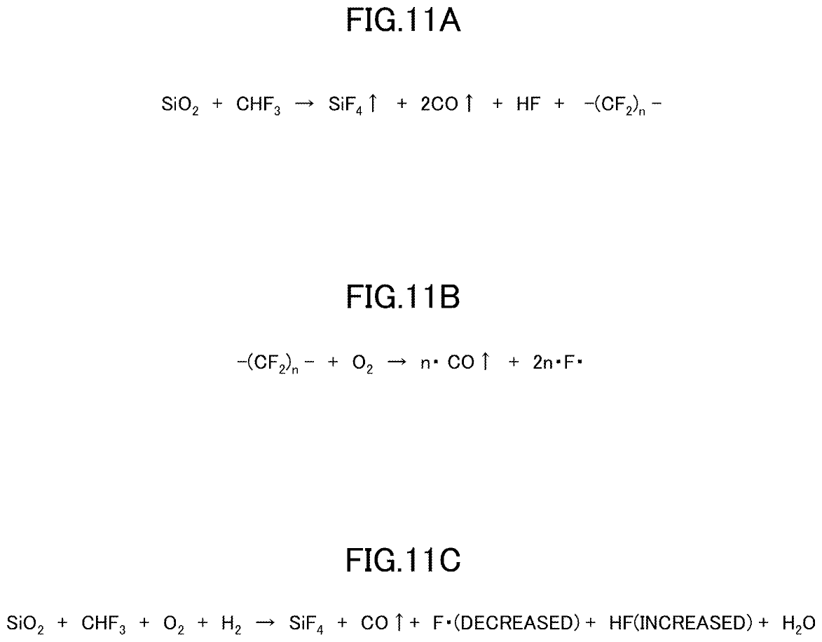

FIGS. 11A to 11C are diagrams describing etching reactions of CHF₃ gases. When a silicon oxide film 202 is exposed to a CHF₃ plasma, a reaction represented by the reaction scheme of FIG. 11A is carried out. Specifically, silicon oxide (SiO₂) and trifluoromethane (CHF₃) are reacted to generate silicon tetrafluoride (SiF₄), carbon monoxide (CO), hydrogen fluoride (HF), and a fluorocarbon polymer film [—(CF₂)ₙ—]. The fluorocarbon polymer film may be also referred to as a polymer hereinafter. In this case, the polymer is deposited in the interior space S, which may lead to generation of particles.

In a case where a plasma is generated using a gas mixture in which an O₂ gas is added to a CHF₃ gas, a reaction represented by the reaction scheme of FIG. 11B is carried out. Specifically, the polymer and O₂ are reacted to decompose the polymer, thereby generating carbon monoxide (CO) and fluorine (F) radicals. In this case, deposition of the polymer in the interior space S can be minimized so that generation of particles can be reduced. In the reaction scheme of FIG. 11B, a symbol “·” represents a radical. Since fluorine radicals increase, members such as quartz and the like inside the vacuum chamber 1 may be etched, or the silicon oxide film 202 may be etched excessively. As a result, a film may be deposited on the top face 201a of the substrate 201 or above the inner face of the recess 201r so that the upper opening of the recess 201r may be narrowed by the polymer.

In a case where a plasma is generated using a gas mixture in which an O₂ gas and a H₂ gas are added to a CHF₃ gas, a reaction represented by the reaction scheme of FIG. 11C is carried out. Specifically, a polymer and O₂ are reacted to generate fluorine radicals; the generated fluorine radicals are reacted with H₂ in the CHF₃/O₂/H₂ plasma to become hydrogen fluoride (HF), thereby reducing an amount of the fluorine radicals. As a result, etching of members such as quartz inside the vacuum chamber 1 or excessive etching of the silicon oxide film 202 is inhibited, while minimizing deposition of the polymer in the interior space S. Therefore, an etching shape where an etching amount gradually decreases from the top to the bottom of the depth direction of the recess 201r, as illustrated in FIG. 10B, can be obtained, while minimizing generation of particles. As a result, bottom-up film formation, in which the silicon oxide film 202 is accumulated from the bottom of the recess 201r to the upper opening, is easily achieved by repeating the etching step S13 and the film formation step S12 to form the silicon oxide film 202 in the recess 201r.

Moreover, the etching shape can be controlled by varying a flow rate of the H₂ gas within the Ar/CHF₃/O₂/H₂ gas. If the flow rate of the H₂ gas within the Ar/CHF₃/O₂/H₂ gas is increased, for example, there is a greater reduction in the amount of fluorine radicals. Therefore, an etching shape where a difference in the etching amount between the top and the bottom of the depth direction of the recess 201r is small is obtained. If the flow rate of the H₂ gas within the Ar/CHF₃/O₂/H₂ gas is reduced, conversely, there is a smaller reduction in the amount of the fluorine radicals. Therefore, an etching shape where a difference in the etching amount between the top and the bottom of the depth direction of the recess 201r is large is obtained. Accordingly, in the etching step S13, the flow rate of the H₂ gas within the Ar/CHF₃/O₂/H₂ gas is preferably determined according to the depth of the recess 201r. In the etching step S13, moreover, the flow rate of the H-gas within the Ar/CHF₃/O₂/H₂ gas is preferably determined according to a targeted etching shape.

After the predetermined time lapse, supply of the Ar/CHF₃/O₂/H₂ gas from the processing gas nozzle 92 is terminated, thereby finishing the etching step S13. The predetermined time lapse is determined, for example, according to the depth of the recess 201r.

In the etching step S13, an Ar gas may be supplied from the reaction gas nozzles 31 and 32.

The determining step S14 is performed after the etching step S13. The determining step S14 includes judging of whether the set number of the film formation steps S12 and the etching steps S13 is performed. When the number of the film formation steps S12 and the etching steps S13 performed has not yet reached the set number (NO in the determining step S14), the film formation step S12 and the etching step S13 are performed again. When the number of the film formation steps S12 and the etching steps S13 performed has reached the set number (YES in the determining step S14), the process is finished. As described above, the film formation step S12 and the etching step S13 are repetitively performed in this order until the number of the steps performed reaches the set number, thereby filling the recess 201r with the silicon oxide film 202 as illustrated in FIG. 10C.

As described above, according to the substrate-processing method according to the present disclosure, a plasma is generated using an Ar/CHF₃/O₂/H₂ gas, and the silicon oxide film 202 is etched by the generated Ar/CHF₃/O₂/H₂ plasma. In this case, a polymer generated by the reaction between the silicon oxide film 202 and CHF₃ is decomposed by the reaction with O₂. Moreover, fluorine radicals generated from the reaction between the polymer and O₂ react with H₂ in the CHF₃/O₂/H₂ plasma to generate hydrogen fluoride, thereby reducing the amount of the fluorine radicals. As a result, etching of members such as quartz and the like inside the vacuum chamber 1 or excessive etching of the silicon oxide film 202 can be inhibited, while minimizing deposition of the polymer in the interior space S. Therefore, an etching shape where an etching amount gently reduces from the top to the bottom of the depth direction of the recess 201r can be obtained, while minimizing generation of particles. As a result, bottom-up film formation, in which the silicon oxide film 202 is accumulated from the bottom of the recess 201r to the upper opening, is easily achieved by repeating the etching step S13 and the film formation step S12 to form the silicon oxide film 202 in the recess 201r. Therefore, the recess 201r of a high aspect ratio can be filled with the silicon oxide film 202 without voids or seams.

According to the substrate-processing method of the present disclosure, moreover, the film formation step S12 and the etching step S13 can be performed by the same substrate-processing apparatus so that a cost of apparatuses can be reduced and productivity is improved.

### Examples

In Examples, an etching amount of a silicon oxide film relative to a depth direction of a recess was measured while varying a flow rate of a H₂ gas in an Ar/CHF₃/O₂/H₂ gas supplied from the processing gas nozzle 92 in the etching step S13.

First, a substrate having a surface where a silicon oxide film was exposed, and having a recess formed therein was provided. The depth of the recess was 7 μm. The thickness of the silicon oxide film was from 30 nm to 40 nm.

Next, the provided substrate was set in the vacuum chamber 1 of the substrate-processing apparatus, and the etching step S13 was performed. In the etching step S13, a flow rate of a H₂ gas was set at 0 sccm, 20 sccm, 50 sccm, or 100 sccm, while fixing a flow rate of an Ar gas to 10,000 sccm, a flow rate of a CHF₃ gas to 100 sccm, and a flow rate of an O₂ gas to 500 sccm.

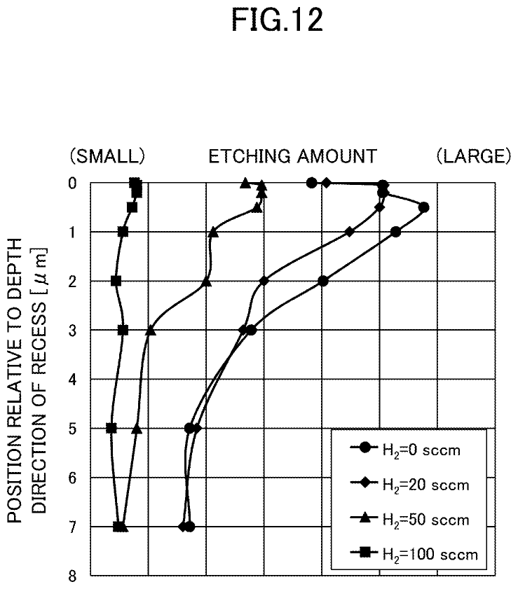

FIG. 12 is a graph depicting an etching amount relative to a depth direction of the recess. In FIG. 12, the vertical axis represents a position [μm] relative to the depth direction of the recess, where the position of 0 μm is the position at the height equal to the top face of the recess, and the position of 7 μm is the position at the height equal to the bottom face of the recess. In FIG. 12, the horizontal axis represents an etching amount of the silicon oxide film. In FIG. 12, a circular mark, a diamond mark, a triangular mark, and a square mark represent examples with the H₂ gas flow rate set at 0 sccm, 20 sccm, 50 sccm, and 100 sccm, respectively.

As depicted in FIG. 12, when the flow rate of the He gas was set at 0 sccm and 20 sccm, the etching amount sharply decreased at the uppermost portion of the recess. When the flow rate of the H-gas was set at 50 sccm and 100 sccm, conversely, the sharp decrease of the etching amount at the uppermost portion of the recess was not observed. It was demonstrated from the above results that, when the flow rate of the H-gas was set at 50 sccm or greater, an etching shape where the etching amount was reduced from the top to the bottom of the recess could be obtained, while inhibiting narrowing of the recess at the uppermost portion of the recess.

As depicted in FIG. 12, when the flow rate of the He gas was set at 100 sccm, the etching amount could be gradually reduced from the top to the bottom of the recess. It was demonstrated from the result above that, when the flow rate of the H-gas was set at 100 sccm, an etching shape where the etching amount was gradually reduced from the top to the bottom of the recess could be formed. In this case, even in the recess of a high aspect ratio, the etching shape where the etching amount was gradually reduced from the top to the bottom of the recess can be formed. Therefore, a filling performance of a film for a recess having a high aspect ratio is improved.

It should be understood that the embodiments disclosed herein are illustrative and not restrictive in all respects. Various omissions, substitutions, and changes may be made to the above-described embodiments without departing from the scope of claims recited and the spirit of the disclosure.

Although the above-described embodiments have been described in the case where a plasma is generated using the Ar/CHF₃/O/H₂ gas in the etching step S13, the present disclosure is not limited to this. For example, an Ar gas may not be included in the gas mixture. For example, another oxygen-containing gas, for example, an ozone (O₃) gas may be used instead of the O₂ gas. For example, another hydrogen-containing gas, for example, an ammonia (NH₃) gas may be used instead of the H₂ gas.

Although the above-described embodiments have been described in the case where the plasma generator 80 is an inductively coupled plasma (ICP) having the antenna 85, the present disclosure is not limited to this. The plasma generator 80 is not limited as long as a plasma can be generated using the Ar/CHF₃/O₂/H₂ gas. For example, the plasma generator 80 may be a capacitively coupled plasma (CCP) that applies high frequency waves between two rod electrodes both parallelly extending to generate a plasma.

Although the above-described embodiments have been described in the case where the substrate-processing apparatus is an apparatus where substrates are processed while rotating the rotary table on which the substrates are mounted, the present disclosure is not limited to this. For example, the substrate-processing apparatus may be an apparatus, which includes a rotation mechanism that rotates the regions of the rotary table where the substrates are mounted so that the substrates mounted on the rotary table themselves are rotated while revolving the substrates with the rotary table, and which processes the substrates mounted on the rotary table while rotating and revolving the substrates. In this case, uniformity of processing across a plane of the substrate is improved.

Although the above-described embodiments have been described in the case where the substrate-processing apparatus is a semi-batch-type apparatus, the present disclosure is not limited to this. For example, the substrate-processing apparatus may be a single wafer processing apparatus configured to process a plurality of substrates one by one. For example, the substrate-processing apparatus may be a batch-type apparatus configured to perform a process to a plurality of substrates all at once.

What is claimed is:

1. A substrate-processing method, comprising:
a) providing a substrate in which a recess is formed, the substrate having a surface where a silicon oxide film is exposed; and
b) generating a plasma using a gas mixture to etch the silicon oxide film with the plasma, the gas mixture including a trifluoromethane gas, an oxygen-containing gas, and a hydrogen-containing gas.

2. The substrate-processing method according to claim 1, wherein a flow rate of the hydrogen-containing gas within the gas mixture is set according to a depth of the recess.

3. The substrate-processing method according to claim 1, wherein b) includes setting a flow rate of the hydrogen-containing gas within the gas mixture according to a targeted etching shape.

4. The substrate-processing method according to claim 1, further comprising:
c) forming a silicon oxide film in the recess, c) being performed after b).

5. The substrate-processing method according to claim 2, further comprising:
c) forming a silicon oxide film in the recess, c) being performed after b).

6. The substrate-processing method according to claim 3, further comprising:
c) forming a silicon oxide film in the recess, c) being performed after b).

7. The substrate-processing method according to claim 4, further comprising:
d) repeating b) and c).

8. The substrate-processing method according to claim 5, further comprising:
d) repeating b) and c).

9. The substrate-processing method according to claim 6, further comprising:
d) repeating b) and c).

10. A substrate-processing apparatus, comprising:
a vacuum chamber;
a gas supply that supplies a gas to the vacuum chamber; and
a controller, wherein
the controller is configured to:
set a substrate in the vacuum chamber, the substrate being a substrate in which a recess is formed and having a surface where a silicon oxide film is exposed; and
expose the substrate to a plasma in the vacuum chamber to etch the exposed silicon oxide film at the surface of the recess, the plasma being generated using a gas mixture including a trifluoromethane gas, an oxygen-containing gas, and a hydrogen-containing gas.
